(19) United States
(12) Patent Application Publication
(10) Pub. No.: US 2006/0041806 A1
(43) Pub. Date: Feb. 23, 2006

(54) Testing method for semiconductor device and testing circuit for semiconductor device

(76) Inventors: Kohei Okada, Yokohama-shi (JP); Junji Mori, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/098,411

(22) Filed: Apr. 5, 2005

(30) Foreign Application Priority Data
Aug. 20, 2004 (JP) 2004-240873

(51) Int. Cl. G01R 31/28

(52) U.S. Cl. 714/726

(57) ABSTRACT

There is provided a testing method for a semiconductor device which has a test object circuit, a non-test object circuit, and a plurality of register circuits which carry out fetching and holding of data based on a clock signal, the semiconductor device including a plurality of first scan chains configured such that the register circuits in the test object circuit are serially connected, and a plurality of second scan chains configured such that the register circuits in the non-test object circuit are serially connected, the testing method including: providing test data to the first and second scan chains, and inputting the clock signal to the first scan chains, not inputting the clock signal to the second scan chains.

### CROSS-REFERENCE TO RELATED APPLICATIONS

This application is based upon and claims the benefit of priority from prior Japanese Patent Application No. 2004-240873, filed Aug. 20, 2004, the entire contents of which are incorporated herein by reference.

### BACKGROUND OF THE INVENTION

1. Field of the Invention

The present invention relates to a testing method and a testing circuit for a semiconductor device, and in particular, to a testing method and a testing circuit for carrying out a test by using a scan test circuit.

2. Description of the Related Art

Tests are implemented in order to distinguish defective goods in a manufacturing process by verifying whether or not electric characteristics, functions, or performances of manufactured LSIs (large-scale integrated circuits) satisfy predetermined standards. However, in recent years, accompanying the increase in the circuit scale of LSIs, the costs required for the tests have been markedly increasing.

Generally, a semiconductor test device is used for an LSI test. However, accompanying the increase in a circuit scale of an LSI, because not only the semiconductor test device to be used is high-priced, but also the number of test patterns for testing LSIs in the semiconductor test device is enormous, the test time per LSI has been markedly increasing.

As a technique of making a test for an LSI easy and of reducing the number of test patterns, there is a scan test system to which a circuit by which data can be set in and read from a flip-flop existing in an LSI is added. This scan test system forms scan chains in which the flip-flops existing in a test object circuit in the LSI are connected in a shift register form. Then, arbitrary data is set in the flip-flops, and an observation of the data stored in the flip-flops is carried out from the outside.

In accordance with the scan test system, the flip-flops in the LSI can be utilized as data input terminals or external observation terminals. In accordance therewith, a sequence circuit requiring an enormous number of input patterns in order to set the internal state of the LSI to a predetermined state can be handled as a combinational circuit whose internal state is not required to be set. As a result, it is easy to automatically generate test patterns used for a test.

However, due to a trend of making LSIs larger scale, the number of test patterns is becoming enormous even in the scan test system. Then, a pseudo random pattern generator (PRPG) serving as a circuit for generating test patterns, a multiple input shift register (MISR) for compressing an executed result of a scan test, or the like have begun to be used.

However, because the compressed data by the MISR is determined to be an operated result, if an indefinite value is input to the MISR, the compressed data as well is made to be indefinite. Therefore, when a test result is compressed by the MISR, a wrapper circuit is inserted into the boundary of a test object circuit and a non-test object circuit. Here, the wrapper circuit is a circuit for making data input from the non-test object circuit to the test object circuit be a fixed value.

FIG. 10 is a circuit diagram showing one example of a wrapper circuit. The wrapper circuit has a flip-flop FF and selectors SEL6, 7. Input data input from the non-test object circuit, scan-in data input from a PRPG, a scan enable signal SCAN_EN input at the time of a scan test, a hold signal, and a clock CLK are input to the wrapper circuit.

Further, the wrapper circuit outputs output data and scan-out data. The output data is input to a combinational circuit of the test object circuit. The scan-out data is input to a wrapper circuit at the next stage.

The wrapper circuit operates in a hold mode and a through mode on the basis of a hold signal. Further, the wrapper circuit selects data to be held, on the basis of a scan enable signal.

Incidentally, with respect to the wrapper circuit, an overhead in an area manner with respect to the test object circuit is great. In particular, when an MISR is hierarchically used, the wrapper circuit is inserted into an internal port of the test object circuit. Therefore, an effect on the area of the test object circuit is further increased.

Further, as this type of related art, a technique as follows is disclosed (refer to Graham Hetherington et al., Logic BIST for Large Industrial Designs: Real Issues and Case Studies, IEEE Proc. INTERNATIONAL TEST CONFERENCE, 1999, pp. 358-367).

### BRIEF SUMMARY OF THE INVENTION

According to a first aspect of the present invention, there is provided a testing method for a semiconductor device which has a test object circuit, a non-test object circuit, and a plurality of register circuits which carry out fetching and holding of data based on a clock signal, the semiconductor device including a plurality of first scan chains configured such that the register circuits in the test object circuit are serially connected, and a plurality of second scan chains configured such that the register circuits in the non-test object circuit are serially connected, the testing method comprising: providing test data to the first and second scan chains, and inputting the clock signal to the first scan chains, not inputting the clock signal to the second scan chains.

According to a second aspect of the present invention, there is provided a testing method for a semiconductor device which has a test object circuit, a non-test object circuit, and a plurality of register circuits which carry out fetching and holding of data based on a clock signal, the semiconductor device including a plurality of first scan chains configured such that the register circuits in the test object circuit are serially connected, and a plurality of second scan chains configured such that the register circuits in the non-test object circuit are serially connected, the testing method comprising: providing test data to the first scan chains, and providing fixed data different from the test data to the second scan chains.

According to a third aspect of the present invention, there is provided a testing circuit for a semiconductor device which has a test object circuit, a non-test object circuit and a plurality of register circuits, the testing circuit comprising: a plurality of first scan chains configured such that the register circuits in the test object circuit are serially connected; a plurality of second scan chains configured such that the register circuits in the non-test object circuit are serially connected; test data input terminals which provide test data to the first and second scan chains; test data output terminals which output test result data from the first scan chains; and a clock control circuit which, after the test data are input to the first and second scan chains, inputs a clock signal to the first scan chain, and does not input the clock signal to the second scan chain.

According to a fourth aspect of the present invention, there is provided a testing circuit for a semiconductor device which has a test object circuit, a non-test object circuit and a plurality of register circuits, the testing circuit comprising: a plurality of first scan chains configured such that the register circuits in the test object circuit are serially connected; a plurality of second scan chains configured such that the register circuits in the non-test object circuit are serially connected; test data input terminals which provide test data to the first and second scan chains; test data output terminals which output test result data from the first and second scan chains; a first clock input terminal which provides a first clock signal to the first scan chains; and a second clock input terminal which provides a second clock signal to the second scan chains.

### BRIEF DESCRIPTION OF THE SEVERAL VIEWS OF THE DRAWING

FIG. 1 is a block diagram showing a configuration of a semiconductor device 1 according to a first embodiment of the present invention;

FIG. 2 is a circuit diagram showing a configuration of a scan cell SCA shown in FIG. 1;

FIG. 3 is a timing chart between a clock CLKA and a clock CLKB at the time of a scan test;

FIG. 4 is a block diagram showing a configuration of the semiconductor device 1 according to a second embodiment of the present invention;

FIG. 5 is a circuit diagram showing a configuration of a clock control circuit 10 shown in FIG. 4;

FIG. 6 is a timing chart of the clock control circuit 10 shown in FIG. 5;

FIG. 7 is a block diagram showing a configuration of the semiconductor device 1 according to a third embodiment of the present invention;

FIG. 8 is a circuit diagram showing a configuration of a fixed data control circuit 20 shown in FIG. 7;

FIG. 9 is a block diagram showing a configuration of the semiconductor device 1 according to a fourth embodiment of the present invention; and

FIG. 10 is a circuit diagram showing one example of a wrapper circuit.

### DETAILED DESCRIPTION OF THE INVENTION

Hereinafter, embodiments of the present invention will be described with reference to the drawings. Note that, in the following descriptions, components having the same functions and configurations are denoted with the same reference numerals, and repeated explanations will be provided only when.

### First Embodiment

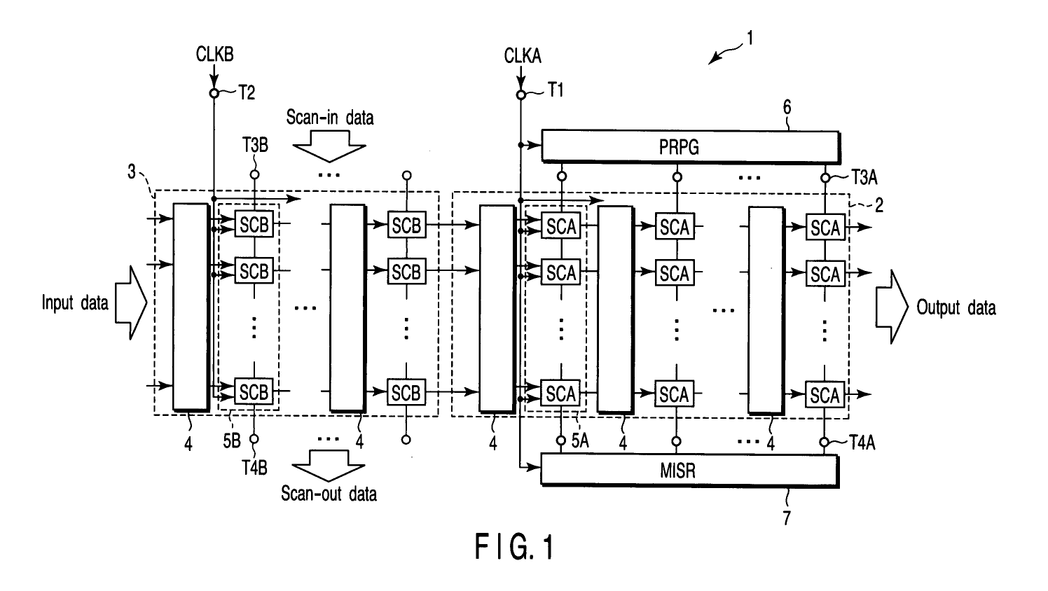

FIG. 1 is a block diagram showing a configuration of a semiconductor device 1 according to a first embodiment of the present invention. The semiconductor device 1 has a test object circuit 2, a non-test object circuit 3, a PRPG 6, and an MISR 7.

The semiconductor device 1 has circuit groups whose clocks are different from one another (for example, a clock domain A and a clock domain B). Then, scan chains are formed for each clock domain. In the present embodiment, the test object circuit 2 corresponds to the clock domain A, and the non-test object circuit 3 corresponds to the clock domain B. Namely, the clock domains of the test object circuit 2 and the non-test object circuit 3 are different from one another.

The test object circuit 2 has a plurality of scan chains 5A and a plurality of combinational circuits 4. Each scan chain 5A has a plurality of scan cells SCA. The scan cells SCA configuring one scan chain 5A are connected in a shift register form.

Further, the non-test object circuit 3 has a plurality of scan chains 5B and a plurality of combinational circuits 4. Each scan chain 5B has a plurality of scan cells SCB. The scan cells SCB configuring one scan chain 5B are connected in the shift register form.

A scan input terminal T3A to which scan-in data which is test data at the time of a scan test is input, and a scan output terminal T4A from which scan-out data which is test result data is output are connected to each scan chain 5A. In the same way, a scan input terminal T3B and a scan output terminal T4B are connected to each scan chain 5B.

The semiconductor device 1 has two clock input terminals T1 and T2 to which system clocks are input from the outside at the time of the scan test. The clock input terminal T1 is connected to the test object circuit 2. The clock input terminal T1 supplies a clock CLKA, which is input from the outside, to the test object circuit 2. The clock input terminal T2 is connected to the non-test object circuit 3. The clock input terminal T2 supplies a clock CLKB, which is input from the outside, to the non-test object circuit 3. In accordance with such a configuration, system clocks can be separately input to the test object circuit 2 and the non-test object circuit 3.

The PRPG 6 is connected to the scan input terminal T3A. The PRPG 6 is composed of a linear feedback shift register (LFSR), and outputs a plurality of test patterns in parallel. The test patterns output from the PRPG 6 are supplied as scan-in data to the test object circuit 2. Note that the clock input terminal T1 is connected to the PRPG 6 as well. The PRPG 6 operates on the basis of the clock CLKA.

The MISR 7 is connected to the scan output terminal T4A. The MISR 7 compresses scan-out data output from the scan output terminal T4A. The MISR 7 is configured so as to attach a tap of an EOR (Exclusive OR) circuit to an LFSR, and is a circuit for outputting a unique expected value compressed result. Note that the clock input terminal T1 is connected to the MISR 7 as well. The MISR 7 operates on the basis of the clock CLKA. The compressed data is stored in, for example, a resister (not illustrated), and is output to the outside.

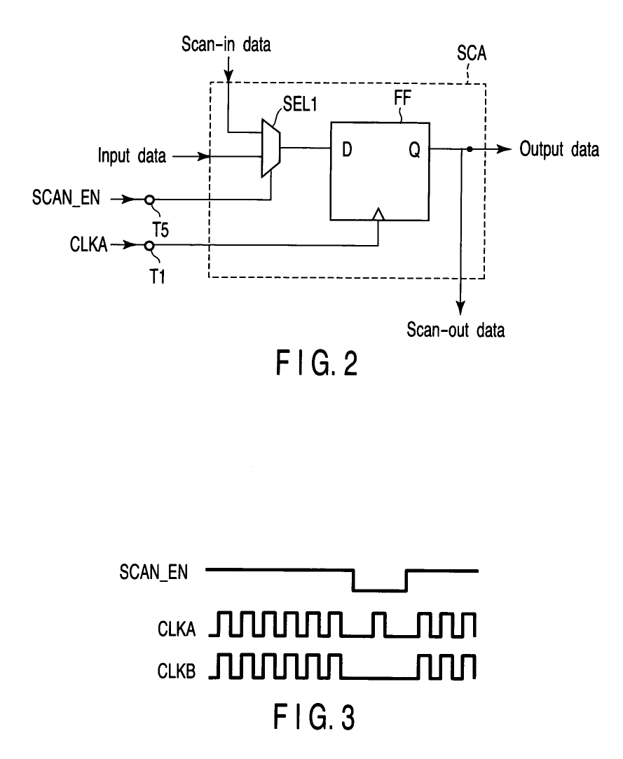

FIG. 2 is a circuit diagram showing a configuration of a scan cell SCA shown in FIG. 1. The scan cell SCA has a register circuit (in the present embodiment, the register circuit comprises, for example, a flip-flop FF) and a selector SEL1.

Scan-in data and input data are input to an input portion of the selector SEL1. Here, the input data is data input from the outside at the time of a normal operation, or data input from the combinational circuit 4. A scan enable terminal T5 is connected to the control terminal of the selector SEL1. A scan enable signal SCAN_EN is input from the outside to the scan enable terminal T5.

The selector SEL1 selects and outputs scan-in data or input data on the basis of the signal SCAN_EN. For example, when the signal SCAN_EN is at a high level, the selector SEL1 outputs input data. On the other hand, when the signal SCAN_EN is at a low level, the selector SEL1 outputs scan-in data.

The input portion D of the flip-flop FF is connected to an output portion of the selector SEL1. The clock input portion of the flip-flop FF is connected to the clock input terminal T1. Namely, the clock CLKA is supplied to a flip-flop FF. The flip-flop FF outputs output data or scan-out data from the output portion Q on the basis of the clock CLKA. The output data is input to the combinational circuit 4 at the following stage. Further, scan-out data is input to the scan cell SCA at the next stage.

Next, the configuration of the scan cell SCB will be described. The clock input portion of the flip-flop FF which the scan cell SCB has is connected to the clock input terminal T2. Namely, the clock CLKB is supplied to the flip-flop FF of the scan cell SCB. The other configurations thereof are the same as those of the scan cell SCA.

Note that, to describe a normal operation simply here, the scan cell SCA operates on the basis of an unillustrated normal clock. For example, the scan cell SCA has a selector (not illustrated) selecting a normal clock and the clock CLKA. Then, the scan cell SCA stores input data, and outputs the stored data as output data to a logic circuit.

Operations of the semiconductor device 1 configured in this way will be described. First, a scan test system will be described.

The semiconductor device 1 has a shift mode for fetching scan-in data into, for example, a scan cell SCA, and a scan mode for carrying out a test in the combinational circuit 4. Then, a scan test is carried out by switching the shift mode and the scan mode.

Concretely, in a case of the shift mode, the semiconductor device 1 inputs scan-in data serially from the scan input terminal T3A, and fetches the scan-in data into the flip-flop FF. Then, when the clock CLKA is input, the semiconductor device 1 shifts the scan-in data to the flip-flop FF at the next stage. By repeating this operation a number of the flip-flops FF in the scan chain 5A, the scan-in data can be set in the combinational circuit 4.

In a case of the scan mode, the semiconductor device 1 fetches output data from the combinational circuit 4 into the flip-flop FF. Then, the semiconductor device 1 switches the mode to the shift mode again, and shifts the data stored in the flip-flop FF, and outputs the data from the scan output terminal T4A. By checking test result data output from the scan output terminal T4A, failure inside the semiconductor device 1 can be detected.

Incidentally, the semiconductor device 1 in the present embodiment forms the scan chains so as to be divided into clock domains A (the test object circuit 2) and clock domains B (the non-test object circuit 3) whose clocks are different from one another. Namely, the test object circuit 2 can be controlled on the basis of the clock CLKA, and on the other hand, the non-test object circuit 3 can be controlled on the basis of the clock CLKB.

FIG. 3 is a timing chart between the clock CLKA and the clock CLKB at the time of a scan test. The scan enable signal SCAN_EN at a high level is input to the scan enable terminal T5. Further, the clock CLKA is input to the clock input terminal T1, and the clock CLKB is input to the clock input terminal T2. In accordance therewith, scan-in data can be set in each combinational circuit 4.

Next, the scan enable signal SCAN_EN at a low level is input to the scan enable terminal T5. Further, a one pulse clock CLKA is input to the clock input terminal T1. In accordance therewith, the scan cell SCA fetches output data from the combinational circuit 4. At that time, a clock is not input to the clock input terminal T2. In accordance therewith, the scan cell SCB does not fetch the output data from the combinational circuit 4, and continues to store the scan-in data.

In this way, it is possible to not change the output data of the scan cell SCB. In accordance therewith, because the data input from the non-test object circuit 3 to the test object circuit 2 does not change, a scan test can be implemented on the assumption that known data is input from the boundary of the non-test object circuit 3 and the test object circuit 2.

Incidentally, the compressed data output from the MISR 7 is determined to be an operated result. Therefore, when an indefinite value is input to the MISR 7, the compressed data as well is made to be indefinite. However, in the present embodiment, because the scan-out data input to the MISR 7 is not made to be indefinite, an accurate scan test can be implemented.

As described above in detail, in the present embodiment, the scan chains are formed so as to be divided into clock domains A and clock domains B whose clocks are different from one another. Then, respectively separate clocks CLKA and CLKB are input to the clock domain A and the clock domain B.

Accordingly, in accordance with the present embodiment, because the data input to the test object circuit 2 can be prevented from being indefinite, there is no need to insert a wrapper circuit or the like into the boundary of the non-test object circuit 3 and the test object circuit 2. In accordance therewith, a circuit area of the semiconductor device 1 having a scan test circuit can be reduced.

Further, the present embodiment is particularly effective in a test circuit using the PRPG 6 and the MISR 7.

### Second Embodiment

In a second embodiment of the present invention, scan chains are formed so as to be divided into the test object circuit 2 and the non-test object circuit 3. Then, the semiconductor device 1 is configured so as to add a circuit for carrying out supplying and stopping the clock CLKA with respect to the test object circuit 2 and the clock CLKB with respect to the non-test object circuit 3.

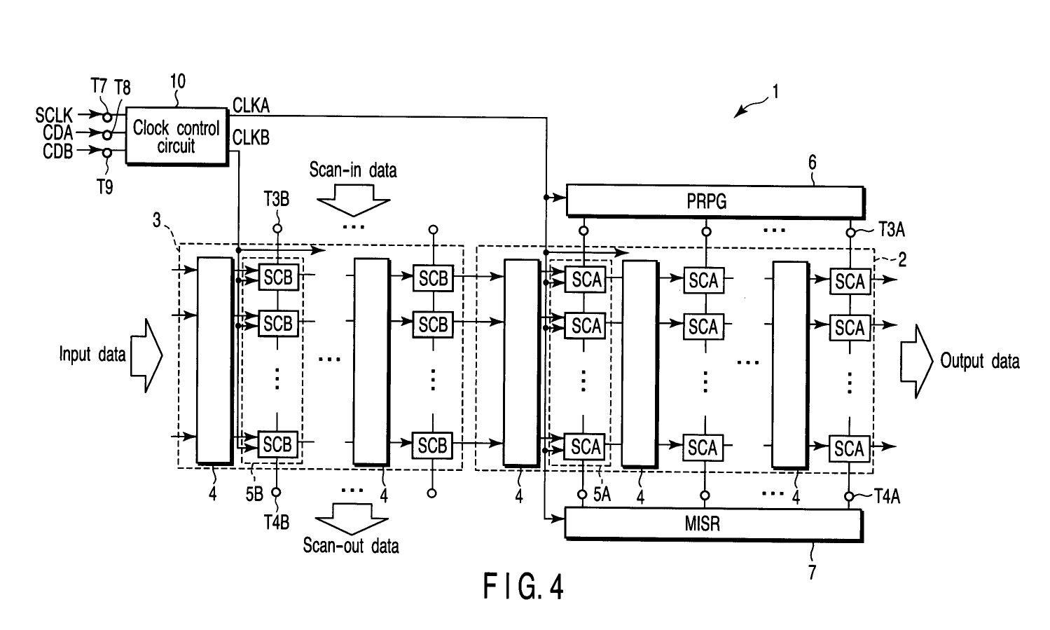

FIG. 4 is a block diagram showing a configuration of the semiconductor device 1 according to the second embodiment of the present invention. The semiconductor device 1 operates on the basis of a single clock. Then, scan chains are formed so as to be divided into the test object circuit 2 and the non-test object circuit 3. At the time of a scan test, the test object circuit 2 operates on the basis of the clock CLKA. Further, the non-test object circuit 3 operates on the basis of the clock CLKB.

The semiconductor device 1 has a clock control circuit 10. A system clock terminal T7 and clock disable terminals T8, T9 are connected to the clock control circuit 10. A system clock SCLK is input from the outside to the system clock terminal T7. A disable signal CDA for stopping the clock CLKA supplied to the test object circuit 2 is input to the clock disable terminal T8 from the outside. A disable signal CDB for stopping the clock CLKB supplied to the non-test object circuit 3 is input to the clock disable terminal T9 from the outside.

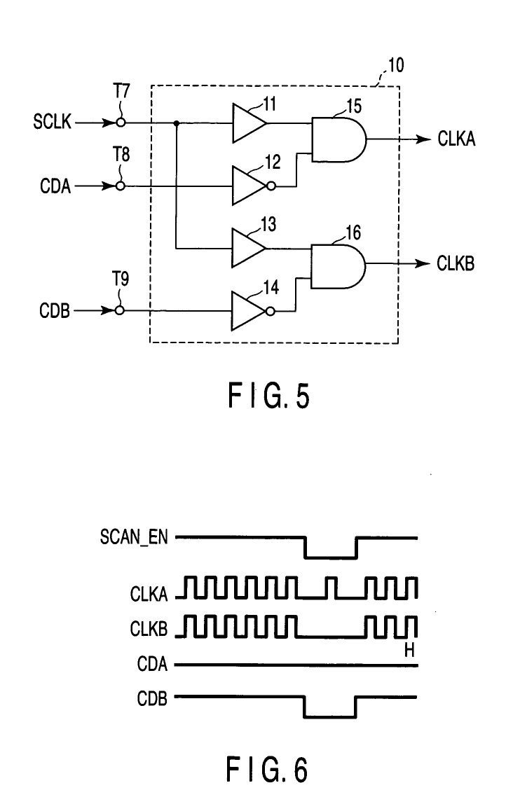

FIG. 5 is a circuit diagram showing a configuration of the clock control circuit 10 shown in FIG. 4. The clock control circuit 10 has buffer circuits 11 and 13, inverter circuits 12 and 14, and AND circuits 15 and 16.

The system clock terminal T7 is respectively connected to the input portions of the buffer circuit 11 and the buffer circuit 13. The clock disable terminal T8 is connected to the input portion of the inverter circuit 12. The clock disable terminal T9 is connected to the input portion of the inverter circuit 14.

The output portions of the buffer circuit 11 and the inverter circuit 12 are respectively connected to the input portions of the AND circuit 15. The output portions of the buffer circuit 13 and the inverter circuit 14 are respectively connected to the input portions of the AND circuit 16. The AND circuit 15 outputs the clock CLKA. The AND circuit 16 outputs the clock CLKB.

Operations of the clock control circuit 10 configured in this way will be described. FIG. 6 is a timing chart of the clock control circuit 10.

A high level scan enable signal SCAN_EN is input to the scan enable terminal T5. Further, the system clock SCLK common with the test object circuit 2 and the non-test object circuit 3 is input to the system clock terminal T7. Further, high level disable signals CDA and CDB are input to the clock disable terminals T8 and T9. In accordance therewith, the system clock SCLK is input to the test object circuit 2 and the non-test object circuit 3. As a result, scan-in data can be set in each combinational circuit 4.

Next, a low level scan enable signal SCAN_EN is input to the scan enable terminal T5. Further, a low level disable signal CDB is input to the clock disable terminal T9. In accordance therewith, it is possible to control such that the system clock SCLK is not input to only the non-test object circuit 3. Namely, the scan cell SCB does not fetch the output data from the combinational circuit 4, and continues to store the scan-in data.

Accordingly, because the data input from the non-test object circuit 3 to the test object circuit 2 does not change, a scan test can be implemented on the assumption that known data is input from the boundary of the non-test object circuit 3 and the test object circuit 2.

Due to the semiconductor device 1 being configured in this way, the same effect as in the first embodiment can be obtained.

Further, even when the semiconductor device 1 operates on the basis of a single clock, the present invention can be applied thereto.

### Third Embodiment

In a third embodiment of the present invention, the semiconductor device 1 is configured such that fixed data is supplied to the non-test object circuit 3 at the time of a scan test.

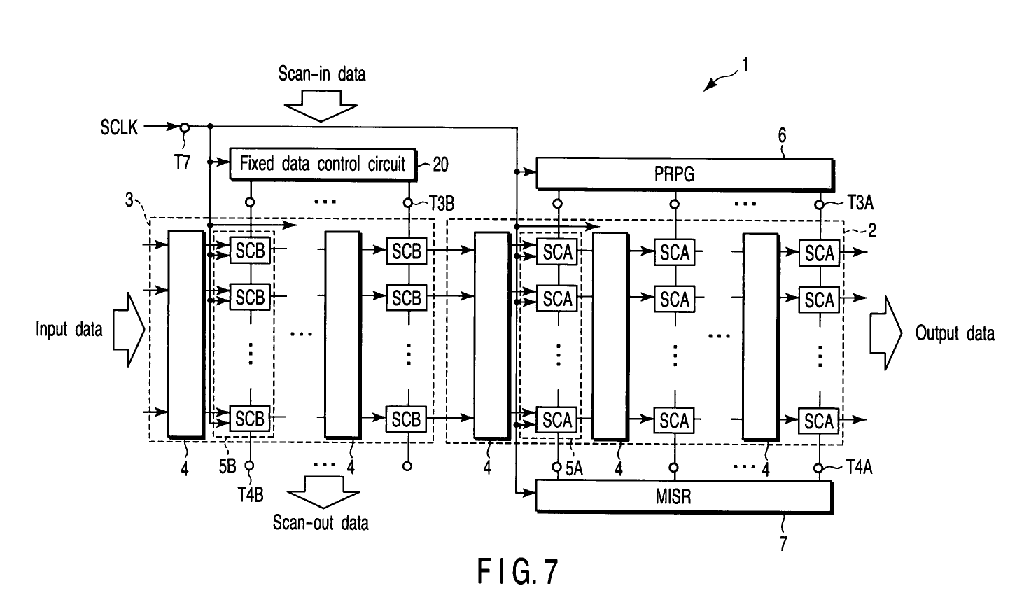

FIG. 7 is a block diagram showing a configuration of the semiconductor device 1 according to the third embodiment of the present invention. The semiconductor device 1 operates on the basis of a single clock. Then, scan chains are formed so as to be divided into the test object circuit 2 and the non-test object circuit 3. At the time of a scan test, the test object circuit 2 and the non-test object circuit 3 operate on the basis of a system clock SCLK.

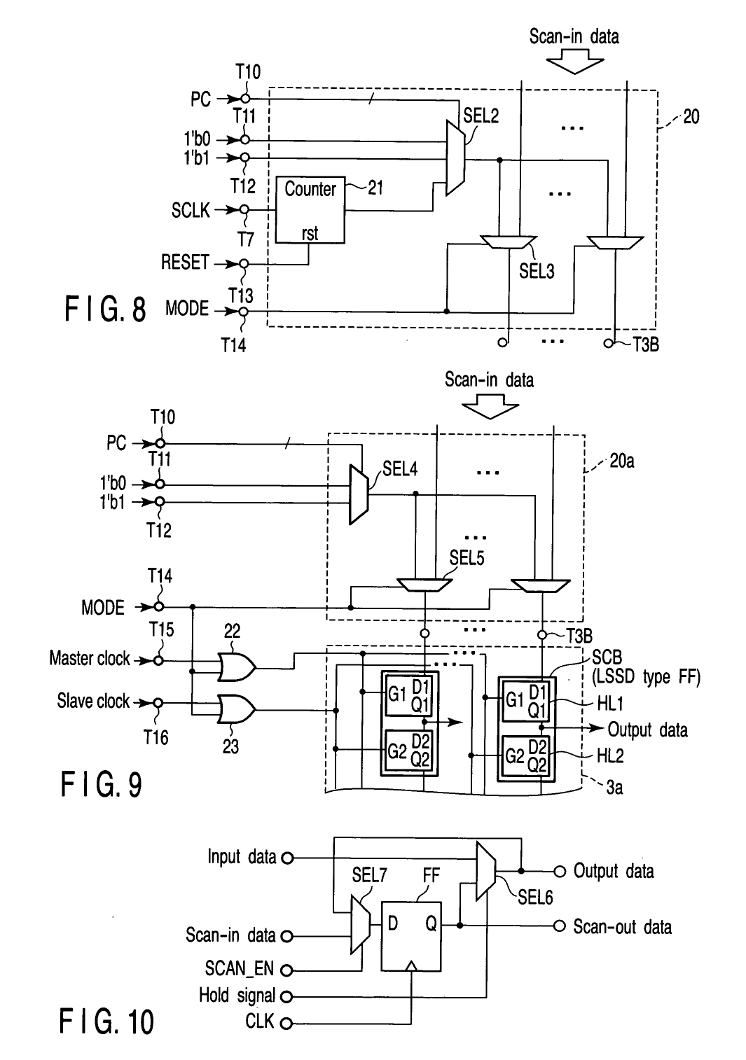

The semiconductor device 1 has a fixed data control circuit 20. FIG. 8 is a circuit diagram showing a configuration of the fixed data control circuit 20 shown in FIG. 7. The fixed data control circuit 20 has a counter 21, a selector SEL2, and selectors SEL3 of a number corresponding to the scan input terminals T3B.

Note that the semiconductor device 1 has a pattern control terminal T10, fixed data input terminals T11 and T12, a reset terminal T13, and a mode switching terminal T14. A signal PC for controlling patterns of fixed data is supplied to the pattern control terminal T10. Data 1′b0 (1 bit/binary/data 0) is supplied to the fixed data input terminal T11 from the outside. Data 1′b1 (1 bit/binary/data 1) is supplied to the fixed data input terminal T12 from the outside.

A reset signal RESET for resetting the counter 21 is supplied to the reset terminal T13 from the outside. A signal MODE for switching a mode in which the fixed data control circuit 20 outputs fixed data, and a mode in which the fixed data control circuit 20 outputs scan-in data is supplied to the mode switching terminal T14 from the outside.

The pattern control terminal T10 is connected to the control terminal of the selector SEL2. The fixed data input terminals T11 and T12 are respectively connected to the input portions of the selector SEL2. The system clock terminal T7 is connected to the input portion of the counter 21. Further, the reset terminal T13 is connected to the reset portion rst of the counter 21. The output portion of the counter 21 is connected to the input portion of the selector SEL2.

The output portion of the selector SEL2 is connected to the input portions of the selectors SEL3. Further, scan-in data is supplied to the input portion of each selector SEL3. The mode switching terminal T14 is connected to the control terminals of the selectors SEL3. The output portions of the selectors SEL3 are connected to the scan input terminals T3B.

Next, operations of the fixed data control circuit 20 will be described. The fixed data control circuit 20 can output fixed data (for example, “000 . . .”, “111 . . .”, “0101 . . .”, or the like) on the basis of the signal PC. Note that the fixed data can be arbitrarily set by a user. The fixed data are not limited to the illustrated data, and may be any data if the user can recognize the data as fixed data.

When fixed data “000 . . .” is output, the selector SEL2 selects the data 1′b0 input from the terminal T11. Concretely, the signal PC making an attempt to select the data 1′b0 is input to the control terminal of the selector SEL2.

When fixed data “111 . . .” is output, the selector SEL2 selects the data 1′b1 input from the terminal T12. Concretely, the signal PC making an attempt to select the data 1′b1 is input to the control terminal of the selector SEL2.

When fixed data “0101 . . .” is output, the selector SEL2 alternately selects the data 1′b0 input from the terminal T11 and the data 1′b1 input from the terminal T12. Concretely, the signal PC making an attempt to alternately select the data 1′b0 and the data 1′b1 is input to the control terminal of the selector SEL2.

Moreover, the fixed data control circuit 20 can output data other than binary data. Namely, the counter 21 counts the pulses of the system clock SCLK, and outputs the counted value. Further, the counter 21 resets the counted value on the basis of a reset signal RESET. The selector SEL2 selects the counted value output from the counter 21.

The selector SEL3 selects scan-in data or fixed data. This selecting operation is carried out on the basis of a signal MODE input to the control terminal of the selector SEL3.

In the semiconductor device 1 configured in this way, at the time of a scan test, the data input from the non-test object circuit 3 to the test object circuit 2 can be a fixed value. In accordance therewith, a scan test can be implemented on the assumption that known data is input from the boundary of the non-test object circuit 3 and the test object circuit 2.

Accordingly, in accordance with the present embodiment, because the data input to the test object circuit 2 can be prevented from being indefinite, there is no need to insert a wrapper circuit or the like into the boundary of the non-test object circuit 3 and the test object circuit 2. In accordance therewith, a circuit area of the semiconductor device 1 having a scan test circuit can be reduced.

### Fourth Embodiment

A fourth embodiment is an embodiment of the present invention when a flip-flop FF configuring a scan cell SCB in a non-test object circuit 3a is a level sensitive scan design (LSSD) type FF.

FIG. 9 is a block diagram showing a configuration of the semiconductor device 1 according to the fourth embodiment of the present invention. The semiconductor device 1 has the non-test object circuit 3a in which the flip-flops FF configuring the scan cells SCB are formed from LSSD type FFs, and a fixed data control circuit 20a.

The fixed data control circuit 20a has a selector SEL4, and selectors SEL5 of a number corresponding to the scan input terminals T3B. The pattern control terminal T10 is connected to the control terminal of the selector SEL4. The fixed data input terminals T11 and T12 are respectively connected to the input portions of the selector SEL4.

The output portion of the selector SEL4 is connected to the input portion of each selector SEL5. Further, scan-in data is supplied to the input portion of each selector SEL5. The mode switching terminal T14 is connected to the control terminals of the selectors SEL5. The output portions of the selectors SEL5 are connected to the scan input terminals T3B.

The fixed data control circuit 20a outputs fixed data (for example, “000 . . .”, “111 . . .”, “0101 . . .”, or the like) on the basis of a signal PC.

The semiconductor device 1 has the pattern control terminal T10, the fixed data input terminals T11 and T12, the mode switching terminal T14, a master clock terminal T15, and a slave clock terminal T16. A master clock is input to the master clock terminal T15. A slave clock is input to the slave clock terminal T16.

The master clock terminal T15 and the mode switching terminal T14 are respectively connected to the input portions of an OR circuit 22. The slave clock terminal T16 and the mode switching terminal T14 are respectively connected to the input portions of an OR circuit 23. The output portion of the OR circuit 22 is connected to gate terminals G1 of LSSD type FFs. The output portion of the OR circuit 23 is connected to gate terminals G2 of LSSD type FFs.

The LSSD type FF is composed of two high through latches HL1 and HL2. The HL1 has a gate terminal G1, an input portion D1, and an output portion Q1. The HL2 has a gate terminal G2, an input portion D2, and an output portion Q2. The input portion D1 is connected to a terminal T3B. The output portion Q1 is connected to the input portion D2. When high level signals are input to the gate terminals G1 and G2, the LSSD type FF fetches data input to the input portion D1, and outputs the data to an LSSD type FF at the next stage from the output portion Q2.

Further, when the master clock is input, the LSSD type FF outputs output data. The output data is input to the combinational circuit 4 at the following stage. Further, when the slave clock is input, the LSSD type FF outputs scan-out data. The scan-out data is input to a scan cell SCB at the next stage.

Operations of the semiconductor device 1 configured in this way will be described. When a signal MODE is at a low level, the selector SEL5 selects scan-in data. The scan-in data is input to the LSSD type FF. The LSSD type FF outputs output data or scan-out data on the basis of the master clock and the slave clock.

When the signal MODE is at a high level, the selector SEL5 selects fixed data. Concretely, the selector SEL5 selects fixed data output from the selector SEL4 on the basis of the signal PC. Further, the high level signal MODE is input to the gate terminals G1 of the LSSD type FFs via the OR circuit 22. In the same way, the high level signal MODE is input to the gate terminals G2 of the LSSD type FFs via the OR circuit 23.

In accordance therewith, each LSSD type FF fetches fixed data and outputs the fixed data to an LSSD type FF at the next stage. Accordingly, fixed data can be set in all the LSSD type FFs in the non-test object circuit 3a without using a clock.

As described above in detail, in the present embodiment, in the semiconductor device 1 using the LSSD type FFs as flip-flops, when fixed data are set in the non-test object circuit 3a, high level signals are supplied to both of the gate terminals G1 and G2.

Accordingly, in accordance with the present embodiment, at the time of setting fixed data in the non-test object circuit 3a, there is no need to shift the level of the fixed data by using a clock. In accordance therewith, because the test time can be shortened, the test costs can be reduced.

Further, at the time of a scan test, the data input from the non-test object circuit 3a to the test object circuit 2 can be a fixed value. In accordance therewith, a scan test can be implemented on the assumption that known data is input from the boundary of the non-test object circuit 3a and the test object circuit 2.

Further, because the data input to the test object circuit 2 can be prevented from being indefinite, there is no need to insert a wrapper circuit or the like into the boundary of the non-test object circuit 3a and the test object circuit 2. In accordance therewith, a circuit area of the semiconductor device 1 having a scan test circuit can be reduced.

Note that, in the present embodiment, the case in which the flip-flops FF configuring the scan cells SCB in the non-test object circuit 3a are LSSD type FFs was described. However, a case in which the flip-flops FF configuring the scan cells SCA in the test object circuit 2 are LSSD type FFs can be implemented in the same way. Namely, a signal MODE is supplied to each scan cell SCA. In accordance therewith, scan-in data input from the PRPG 6 to the test object circuit 2 can be set in all the LSSD type FFs in the test object circuit 2.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A testing method for a semiconductor device which has a test object circuit, a non-test object circuit, and a plurality of register circuits which carry out fetching and holding of data based on a clock signal, said semiconductor device including a plurality of first scan chains configured such that the register circuits in the test object circuit are serially connected, and a plurality of second scan chains configured such that the register circuits in the non-test object circuit are serially connected, said testing method comprising:
providing test data to the first and second scan chains, and
inputting the clock signal to the first scan chains, not inputting the clock signal to the second scan chains.

2. The testing method for the semiconductor device, according to claim 1, wherein
the semiconductor device further comprises a plurality of selecting circuits which are respectively connected to the register circuits, and which select input data input from a plurality of combinational circuits disposed between the respective first scan chains and between the respective second scan chains, and the test data.

3. A testing method for a semiconductor device which has a test object circuit, a non-test object circuit, and a plurality of register circuits which carry out fetching and holding of data based on a clock signal, said semiconductor device including a plurality of first scan chains configured such that the register circuits in the test object circuit are serially connected, and a plurality of second scan chains configured such that the register circuits in the non-test object circuit are serially connected, said testing method comprising:
providing test data to the first scan chains, and
providing fixed data different from the test data to the second scan chains.

4. The testing method for the semiconductor device, according to claim 3, wherein
the semiconductor device further includes a plurality of selecting circuits which are respectively connected to the register circuits, and which select input data input from a plurality of combinational circuits disposed between the respective first scan chains and between the respective second scan chains, and the test data.

5. A testing circuit for a semiconductor device which has a test object circuit, a non-test object circuit and a plurality of register circuits, said testing circuit comprising:
a plurality of first scan chains configured such that the register circuits in the test object circuit are serially connected;
a plurality of second scan chains configured such that the register circuits in the non-test object circuit are serially connected;
test data input terminals which provide test data to the first and second scan chains;
test data output terminals which output test result data from the first scan chains; and
a clock control circuit which, after the test data are input to the first and second scan chains, inputs a clock signal to the first scan chain, and does not input the clock signal to the second scan chain.

6. The testing circuit for the semiconductor device, according to claim 5, further comprising a plurality of selecting circuits which are respectively connected to the plurality of register circuits, and which select input data input from a plurality of combinational circuits disposed between the respective first scan chains and between the respective second scan chains, and the test data, and wherein the respective register circuits carry out fetching and holding of the input data or the test data based on the clock signal.

7. The testing circuit for the semiconductor device, according to claim 6, wherein
the clock control circuit includes a clock terminal to which the clock signal is input, and a second control terminal to which a second control signal denoting whether or not the clock signal is input to the second scan chains is input.

8. The testing circuit for the semiconductor device, according to claim 7, wherein
the clock control circuit includes a first control terminal to which a first control signal denoting whether or not the clock signal is input to the first scan chains is input.

9. The testing circuit for the semiconductor device, according to claim 5, wherein the respective register circuits are formed from flip-flops.

10. A testing circuit for a semiconductor device which has a test object circuit, a non-test object circuit and a plurality of register circuits, the testing circuit comprising:
a plurality of first scan chains configured such that the register circuits in the test object circuit are serially connected;
a plurality of second scan chains configured such that the register circuits in the non-test object circuit are serially connected;
test data input terminals which provide test data to the first and second scan chains;
test data output terminals which output test result data from the first and second scan chains;
a first clock input terminal which provides a first clock signal to the first scan chains; and
a second clock input terminal which provides a second clock signal to the second scan chains.

11. The testing circuit for the semiconductor device, according to claim 10, further comprising a plurality of selecting circuits which are respectively connected to the plurality of register circuits, and which select input data input from a plurality of combinational circuits disposed between the respective first scan chains and between the respective second scan chains, and the test data, wherein
the respective register circuits carry out fetching and holding of the input data or the test data based on the first clock signal or the second clock signal.

12. The testing circuit for the semiconductor device, according to claim 10, wherein
the test data input terminals include first test data input terminals which provide the test data to the first scan chains, and second test data input terminals which provide the test data to the second scan chains, and
the testing circuit further comprises a first data generating circuit which is connected to the second test data input terminals, and which generates fixed data different from the test data.

13. The testing circuit for the semiconductor device, according to claim 12, further comprising a second data generating circuit which is connected to the first test data input terminals, and which generates the test data.

14. The testing circuit for the semiconductor device, according to claim 10, wherein
the test data output terminals include first test data output terminals which output the test result data from the first scan chains, and second test data output terminals which output the test result data from the second scan chains, and
the testing circuit further comprises an output circuit which is connected to the first test data output terminals, and which outputs the test result data to the outside.

15. The testing circuit for the semiconductor device, according to claim 10, wherein the respective register circuits are formed from flip-flops.

16. The testing circuit for the semiconductor device, according to claim 11, wherein the respective register circuits are formed from level sensitive scan design (LSSD) type flip-flops, and
the testing circuit further comprises a control circuit which makes the register circuits execute fetching and holding of the test data almost simultaneously.

17. The testing circuit for the semiconductor device, according to claim 16, wherein
the respective register circuits have first gates to which a master clock signal for outputting the input data is input, and second gates to which a slave clock signal for outputting the test data is input, and
the control circuit inputs high level signals to the first and second gates.
